(19) United States
(12) Patent Application Publication
(10) Pub. No.: US 2002/0020921 A1
(43) Pub. Date: Feb. 21, 2002

(54) Structure of an ink-jet printhead chip and manufacturing method thereof

(76) Inventors: Chieh-Wen Wang, Hsinchu (TW); Ming-Ling Lee, Hsinchu (TW); Yuan-Liang Lan, Hsinchu Hsien (TW); Yi-Yung Wu, Taichung Hsien (TW); Hui-Fang Wang, Taichung Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 09/838,434

(22) Filed: Apr. 19, 2001

Related U.S. Application Data
(62) Division of application No. 09/128,223, filed on Aug. 3, 1998.

(30) Foreign Application Priority Data
May 20, 1998 (TW) 87107718

(51) Int. Cl. H01L 23/48; H01L 23/52; H01L 29/40

(52) U.S. Cl. 257/774; 257/734

(57) ABSTRACT

A method of manufacturing a printhead chip comprising the steps of first forming a resistive layer and a conductive layer over a substrate, wherein the resistive layer and the conductive layer act as a heater and a conductive line respectively. Thereafter, at least one insulating layer is deposited over the conductive layer and the resistive layer. Next, at least one metallic layer is deposited over the insulating layer without performing any intermediate photolithographic or etching operations, and then the metallic layer is patterned to form a contact opening. The contact opening passes through the metallic layer and the insulating layer while exposing a portion of the conductive layer. Subsequently, a metal plug is formed in the contact opening so that the metallic layer and the conductive layer are connected, thereby forming an electric circuit. Finally, a thick film is formed over the metallic layer acting as an ink channel for the printhead.

### CROSS-REFERENCE TO RELATED APPLICATION

This application claims the priority benefit of Taiwan application Ser. no. 87107718, filed May 20, 1998, the full disclosure of which is incorporated herein by reference.

### BACKGROUND OF THE INVENTION

1. Field of Invention

The present invention relates to a structure and a method for manufacturing inkjet printhead. More particularly, the present invention relates to a structure of an inkjet printhead chip and a manufacturing method thereof.

2. Description of Related Art

The process of manufacturing a conventional printhead chip, for example, a thermal bubble printhead is described in detail such as U.S. Pat. No. 4,862,197. Below is a brief summary of its method of manufacture and structure as well as some intrinsic defects in the conventional manufacturing techniques.

FIG. 1 is a cross-sectional view showing the structure of a conventional thermal bubble printhead chip. The method of manufacturing the chip includes sequentially forming a resistive layer 102 and a conductive layer 104 over a substrate 100. Thereafter, the resistive layer 102 and the conductive layer 104 are patterned to form a heater and a conductive line respectively. Then, at least a layer of insulating material is deposited over the resistive layer 102 and the conductive layer 104.

In FIG. 1, two insulating layers 106 and 108 are deposited. The insulating layers 106 and 108 can be made from material including, for example, silicon nitride (SiNₓ) or silicon carbide (SiCₓ). Subsequently, a contact opening is formed, and then at least one layer of metal is deposited to fill the contact opening.

In FIG. 1, two layers of metals 110 and 112 are deposited. The metallic layers 110 and 112 can be made from material including, for example, tantalum (Ta) or gold (Au). Through the metallic layers 110 and 112 in the contact opening, connection is made with the conductive layer 104 below and a complete electric circuit is established. Thereafter, as shown in FIG. 1, a bonding point for TAB 116 and a thick film 114 that acts as an ink channel is formed above the metallic layer 112. In general, in order to lower contact resistance and to obtain a smooth connection for the electric circuit, the layer above the metallic layer 110 is made particularly thick so that the contact opening can be completely covered.

In the conventional method, the insulating layers 106 and 108 has to be patterned before the metallic layers 110 and 112 are deposited, and hence adhesion of the metallic layer 110 for the insulating layer 108 is affected. Therefore, the working life of the chip in the printhead is lowered as well. This is because when an insulating layer undergoes photolithographic and etching operations, a layer of photoresist must be formed over the insulating layer and then subsequently removed. Normally, water and some organic solvents are used for cleaning the silicon surface after the photoresist layer is removed.

However, organic residues are often deposited above the insulating layer. Sometimes, these organic residues may react chemically forming bonds with the surface molecules of the insulating layer making its removal particularly difficult. Subsequently, when metal is deposited, adhesion for the insulating layer is weakened.

Due to the presence of foreign particles at the interface between the insulating layer and the metallic layer, adhesion of the metallic layer for the insulating layer after deposition deteriorates and hence the yield rate is low. Furthermore, non-uniformity of deposition will also lead to uneven heat transfer, which may overheat some part and shorten the working life of the heater. Moreover, the metallic layer must have a thickness thick enough for completely covering the contact opening, thereby compromising heat transfer efficiency. In light of the foregoing, there is a need to provide an improved structure and method of manufacturing the printhead chip.

### SUMMARY OF THE INVENTION

Accordingly, the present invention is to provide a method of manufacturing the printhead chip. The method is to deposit a metallic layer over an insulating layer immediately after the insulating layer is formed so that adhesion of the metallic layer for the insulating layer is increased, and so a longer working life for the printhead is obtained.

In another aspect, this invention is to provide a method of manufacturing the printhead chip, wherein the upper metallic layer and the lower conductive layer are connected through a metal plug. Hence, the required thickness of the metallic layer is greatly reduced and thermal transfer efficiency is increased. In addition, production yield and stability of the manufacturing process can be increased.

In one further aspect, this invention is to provide a structure for an ink-jet printhead chip.

To achieve these and other advantages and in accordance with the purpose of the invention, as embodied and broadly described herein, the invention provides a method of manufacturing the printhead chip. The method comprises the steps of first forming a resistive layer and a conductive layer over a substrate, wherein the resistive layer and the conductive layer act as a heater and a conductive line respectively. Thereafter, at least one insulating layer is deposited over the conductive layer and the resistive layer. Next, at least one metallic layer is deposited over the insulating layer without performing any intermediate photolithographic or etching operations, and then the metallic layer is patterned to form a contact opening. The contact opening passes through the metallic layer and the insulating layer while exposing a portion of the conductive layer. Subsequently, a metal plug is formed within the contact opening so that the metallic layer and the conductive layer are connected, thereby forming an electric circuit. Finally, a thick film is formed over the metal plug acting as an ink channel for the printhead.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view showing the structure of a conventional thermal bubble printhead chip;

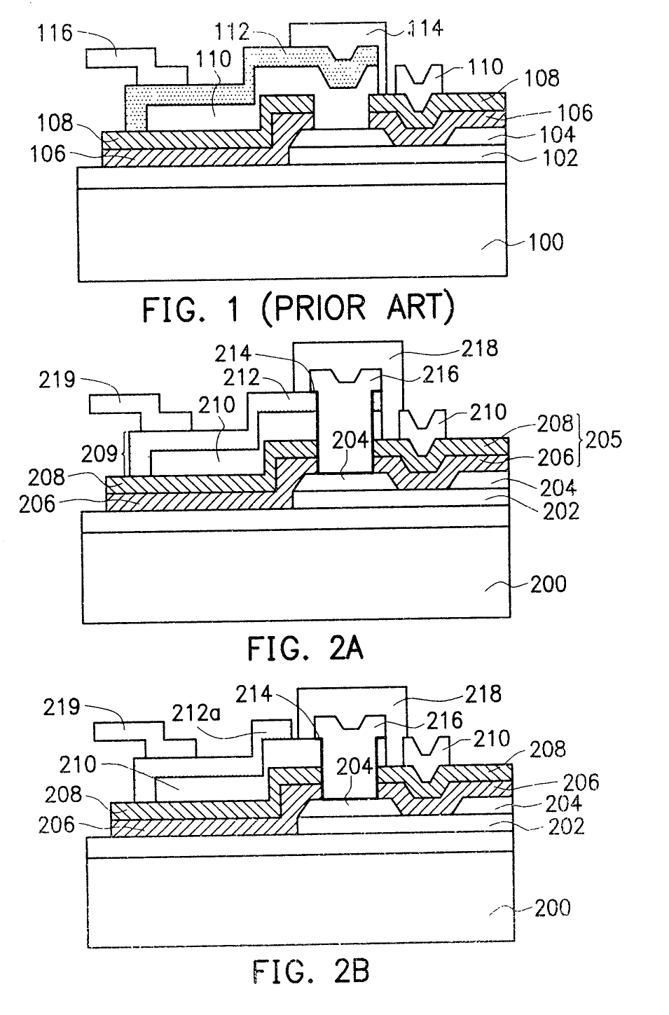

FIGS. 2A and 2B are cross-sectional views showing two chip structures according to the embodiments of this invention; and

FIGS. 3A through 3G are cross-sectional views showing the progression of manufacturing steps in fabricating the thermal bubble printhead chip according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

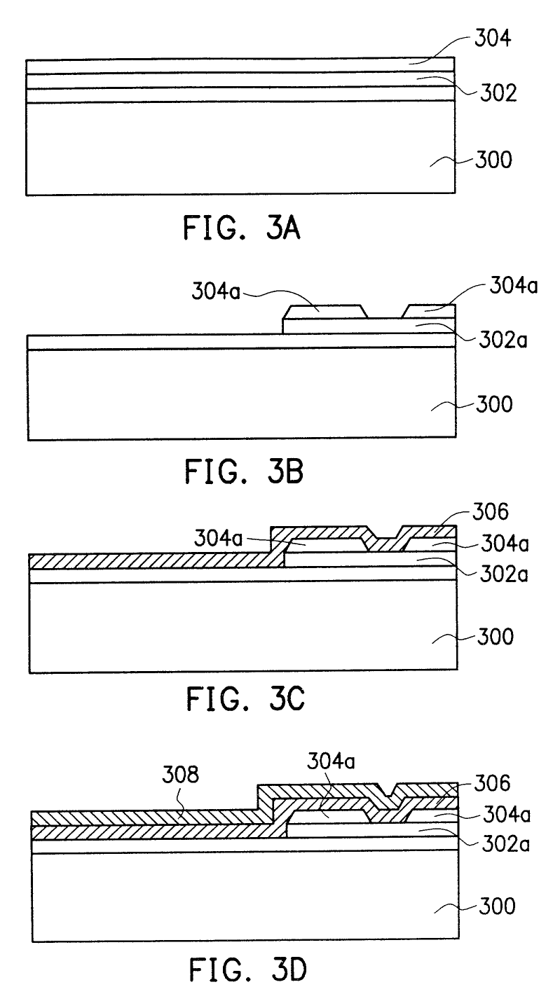

FIGS. 2A and 2B are cross-sectional views showing two chip structures according to the embodiments of this invention.

First, as shown in FIG. 2A, the chip structure is formed above a substrate 200. Above the substrate 200 a resistive layer 202 and a conductive layer 204 are formed, wherein the conductive layer 204 is located above the resistive layer 202. There is an insulating layer 205 over the conductive layer 204. As shown in FIG. 2A, the insulating layer 205 is a two-layered structure that includes insulating layers 206 and 208.

The insulating layers 206 and 208 can be formed from material including, for example, silicon nitride (SiNₓ) and silicon carbide (SiCₓ). The insulating layers 206 and 208 serve as isolating and protecting layers for the conductive layer 204 and the resistive layer 202. Besides the two-layered structure, the insulating layer 205 can also be a single layer or a multi-layered structure as well.

Above the insulating layers 206 and 208, there is a metallic layer 209. In FIG. 2A, the metallic layer 209 is, for example, a double-layered structure including metallic layers 210 and 212. The metallic layers 210 and 212 are preferably tantalum (Ta) layer and gold (Au) layer respectively. Similarly, besides a two-layered metallic layer structure, the metallic layer 209 can be a single layer or a multi-layered structure as well.

Furthermore, there is a contact opening 214 above the conductive layer 204. The contact opening 214 penetrates through the metallic layers 210, 212 and the insulating layers 206, 208 so that a portion of the conductive layer 204 is exposed. Inside the contact opening 214, there is a metal plug 216. The metal plug 216 connects the metallic layers 210, 212 and the conductive layer 204 electrically. In addition, there is a thick film 218 above the metal plug 216 serving as an ink channel for the printhead.

The structure of the chip provides a electric circuit. The circuit starts out from the metallic gold (Au) layer 212 through the metallic tantalum (Ta) layer 210, the metal plug 216, the conductive layer 204, the resistive layer 202 and then back through the conductive layer 204, the metal plug 216, the metallic tantalum (Ta) layer 210 and finally the metallic gold (Au) layer 212.

Another structure of the chip similar to FIG. 2A is shown in FIG. 2B. Those parts in FIG. 2B that are identical to FIG. 2A are labeled similarly. In FIG. 2B, the main difference from FIG. 2A is that although the metallic gold (Au) layer 212a still lies above the metallic tantalum (Ta) layer 210, it does not directly connect with the metal plug 216. Despite the difference, the chip in FIG. 2B is still capable of providing the same type of electric circuit as in FIG. 2A.

Furthermore, in FIGS. 2A and 2B, the metal plug 216 completely fills the contact opening 214. However, in practice, the metal plug 216 can fill the contact opening 214 only partially.

According to the above ink-jet printhead structures, a method of manufacturing the chip is provided below. The method of this invention includes depositing a metallic layer over an insulating layer immediately after the insulating layer is formed. Next, a contact opening that penetrates through the metallic layer and the insulating layer is formed exposing a portion of the conductive layer. Subsequently, a metal plug is formed inside the contact opening so that the metallic layer and the conductive layer are electrically connected, thereby forming an electric circuit. The electric circuit is used for powering the resistive layer of the heater.

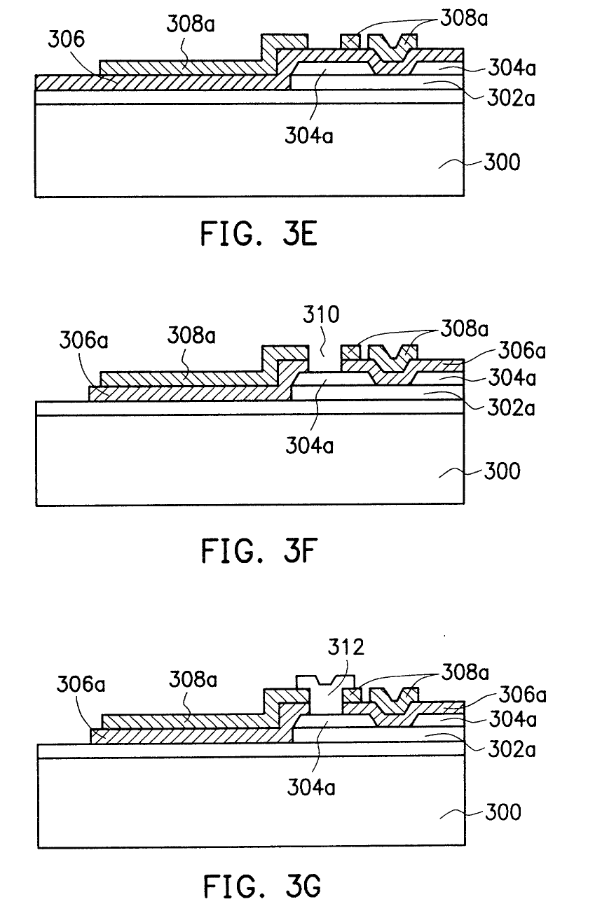

FIGS. 3A through 3G are cross-sectional views showing the progression of manufacturing steps in fabricating the thermal bubble printhead chip according to one preferred embodiment of this invention.

First, as shown in FIG. 3A, a resistive layer 302 and a conductive layer 304 are deposited over a substrate 300. The resistive layer 302 can be made from compounds including, for example, hafnium boride (HfB₂), tantalum aluminum (TaAl), and tantalum nitride (TaN). The conductive layer 304 can be made from metallic material including, for example, aluminum (Al) and aluminum-copper alloy (Al-Cu).

Next, as shown in FIG. 3B, a photolithographic operation applied on the resistive layer 302 and the conductive layer 304 is carried out forming a pattern. The patterned resistive layer 302a and conductive layer 304a are later used as the respective heater and conductive line of the printhead chip.

Thereafter, as shown in FIG. 3C, a chemical vapor deposition method, for example, is used to deposit an insulating layer 306 over the resistive layer 302a and the conductive layer 304a. The insulating layer 306 serves as an isolating and protecting layer for the resistive layer 302a and the conductive layer 304a. The insulating layer 306 can be made from material including silicon nitride (SiNₓ) or silicon carbide (SiCₓ). In addition, the insulating layer 306 does not have to be deposited as a single layer. The insulating layer 306 can be double-layered as shown in FIGS. 2A and 2B, in which one is a silicon nitride layer while the other is a silicon carbide layer, or can be more than two layers as well.

Next, as shown in FIG. 3D, a metallic layer 308 is immediately deposited over the insulating layer 306 without first going through photolithographic and etching operations as required by a conventional method. Because the metallic layer 308 is deposited directly without any intermediate steps, no contaminants are formed between the insulating layer 306 and the metallic layer 308. Therefore, adhesion of the metallic layer for the insulating layer 306 is correspondingly higher and working life of the printhead chip is longer. Similarly, the metallic layer does not have to be deposited as a single layer. The metallic layer 308 can be double-layered as shown in FIGS. 2A and 2B, in which sputtering or thermal evaporation method is used to deposit a tantalum (Ta) layer and a gold (Au) layer respectively.

Subsequently, as shown in FIG. 3E, a photolithographic operation of the metallic layer 308 is carried out to form a metallic layer pattern 308a. Next, as shown in FIG. 3F, the exposed insulating layer 306 undergoes a photolithographic and patterning operation to form an insulating layer 306a. Consequently, a contact opening 310 that passes through the metallic layer 308a and the insulating layer 306a exposing a portion of the conductive layer 304a is formed.

Next, as shown in FIG. 3F, a metal plug 312 is formed inside the contact opening 310 for connecting the metallic layer 308a and the conductive layer 304a electrically. The metal plug 312 can be formed using a sputtering method, a thermal evaporation method or a chemical vapor deposition method. Since the metallic layer 308a and the conductive layer 304a are connected by a metal plug 312, it is unnecessary to have a very thick metallic layer 308 as in the conventional technique. In fact, thickness of the metallic layer formed by the method of this invention is about half the thickness of a conventionally formed metallic layer. Moreover, the metal plug 312 can also be formed by using a lift-off process in combination with a thermal evaporation process.

In summary, one aspect of this invention is the immediate deposition of a metallic layer over the insulating layer without any intermediate operations. Hence contamination of the metal/insulating layer interface that can reduce adhesion of the metallic layer for the insulating layer is prevented. Therefore, the invention is capable of increasing the adhesion between the metallic layer and the insulating layer, the production yield and the working life of the ink-jet printhead.

One further aspect of this invention is the use of a metal plug for connecting the metallic layer and the conductive layer electrically. Consequently, there is no need to deposit a rather thick layer of metallic layer. With a thinner metallic layer, production yield and process stability is raised. Furthermore, high heat transfer efficiency can be obtained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing an ink-jet printhead chip above a substrate, comprising:
forming a resistive layer and a conductive layer over the substrate, and then patterning the resistive layer and the conductive layer;
forming an insulating layer over the conductive layer and the resistive layer;
forming a metallic layer over the insulating layer, and then patterning the metallic layer and the insulating layer to form a contact opening that penetrates through the metallic layer and the insulating layer while exposing a portion of the conductive layer; and
forming a metal plug inside the contact opening.

2. The method of claim 1, wherein the step of forming the insulating layer comprises depositing a single layer.

3. The method of claim 1, wherein the step of forming the insulating layer comprises depositing a multiple of layers.

4. The method of claim 1, wherein the step of forming the insulating layer comprises depositing silicon nitride (SiNₓ).

5. The method of claim 1, wherein the step of forming the insulating layer comprises depositing silicon carbide (SiCₓ).

6. The method of claim 1, wherein the step of forming the insulating layer comprises a chemical vapor deposition method.

7. The method of claim 1, wherein the step of forming the metallic layer comprises depositing a single layer.

8. The method of claim 1, wherein the step of forming the metallic layer includes depositing a multiple of layers.

9. The method of claim 1, wherein the step of forming the metallic layer includes a sputtering method.

10. The method of claim 1, wherein the step of forming the metallic layer includes depositing using a thermal evaporation method.

11. The method of claim 1, wherein the step of forming the metallic layer includes depositing tantalum (Ta).

12. The method of claim 1, wherein the step of forming the metallic layer includes depositing gold (Au).

13. The method of claim 1, wherein the step of forming the metal plug includes depositing metallic material to fill the contact opening completely.

14. The method of claim 1, wherein the step of forming the metal plug includes depositing metallic material to fill the contact opening partially.

15. The method of claim 1, wherein the step of forming the metal plug includes a chemical vapor deposition method.

16. The method of claim 1, wherein the step of forming the metal plug includes depositing using a thermal evaporation method.

17. The method of claim 1, wherein the step of forming the metal plug includes a sputtering method.

18. The method of claim 1, wherein the step of forming the metal plug includes a lift-off method.

19. The method of claim 1, wherein the step of forming the metal plug includes depositing a single layer.

20. The method of claim 1, wherein the step of forming the metal plug includes depositing a multiple of layers.

21. The method of claim 1, wherein the step of forming the metal plug includes depositing a conductive material selected from a group materials including gold, tantalum, aluminum, chromium, copper, indium, tin, tantalum-aluminum alloy, tantalum-silicon alloy, tantalum-tungsten alloy, aluminum-copper alloy, aluminum-silicon-copper alloy, indium-tin alloy, gold-tin alloy and lead-tin alloy.

22. A chip structure mounted on a substrate for an ink-jet printhead, comprising:
a resistive layer and a conductive layer above the substrate, wherein the conductive layer is located above the resistive layer;
an insulating layer above the conductive layer;
a metallic layer above the insulating layer;
a contact opening that passes through the metallic layer and the insulating layer while exposing a portion of the conductive layer; and
a metal plug within the contact opening for connecting the metallic layer and the conductive layer.

23. The structure of claim 22, wherein the structure further includes a thick film above the metal plug acting as a channel for the ink.

24. The structure of claim 22, wherein the insulating layer is a single layer structure.

25. The structure of claim 22, wherein the insulating layer is a multi-layered structure.

26. The structure of claim 22, wherein the metallic layer is a single layer structure.

27. The structure of claim 22, wherein the metallic layer is a multi-layered structure.

28. The structure of claim 22, wherein the metal plug is a single layer structure.

29. The structure of claim 22, wherein the metal plug is a multi-layered structure.

30. The structure of claim 22, wherein the metal plug completely fills the contact opening.

31. The structure of claim 22, wherein the metal plug fills the contact opening only partially.
